(19) United States
(12) Patent Application Publication
(10) Pub. No.: US 2013/0320296 A1
(43) Pub. Date: Dec. 5, 2013

(54) LIGHT EMITTING DEVICE WITH QCSE-REVERSED AND QCSE-FREE MULTI QUANTUM WELL STRUCTURE

(71) Applicants: Chun-Ta Yu, Hsinchu (TW); Chien-Yuan Tseng, Hsinchu (TW); Yu-Yao Lin, Hsinchu (TW); Shih-Pang Chang, Hsinchu (TW); Hung-Chih Yang, Hsinchu (TW)

(72) Inventors: Chun-Ta Yu, Hsinchu (TW); Chien-Yuan Tseng, Hsinchu (TW); Yu-Yao Lin, Hsinchu (TW); Shih-Pang Chang, Hsinchu (TW); Hung-Chih Yang, Hsinchu (TW)

(73) Assignee: Epistar Corporation, Hsinchu (TW)

(21) Appl. No.: 13/488,764

(22) Filed: Jun. 5, 2012

(51) Int. Cl. H01L 33/04

(52) U.S. Cl. 257/13; 257/E33.008

(57) ABSTRACT

A light-emitting device comprises a semiconductor stacked structure, the semiconductor stacked structure comprising a p-type semiconductor layer, a n-type semiconductor layer and an multiple quantum well structure between the p-type semiconductor layer and the n-type semiconductor layer, wherein the multiple quantum well structure comprises a first multiple quantum well structure near the n-type semiconductor layer and a second multiple quantum well structure near the p-type semiconductor layer, wherein the first multiple quantum well structure has positive interface bound charge and the second multiple quantum well structure has zero interface bound charge.

### TECHNICAL FIELD

The present application generally relates to a nitride-based light-emitting device, and, more particularly, to a nitride-based light-emitting device with the multiple quantum well which includes reversed quantum confined Stark effect (QCSE-reversed) and free quantum confined Stark effect (QCSE-free).

### DESCRIPTION OF BACKGROUND ART

As the light-emitting efficiency is increased and the cost of manufacturing is decreased, the dream for solid lighting device to replace the traditional lighting device may come true in recent years. Generally, white light is provided by using blue light to excite the yellow phosphor, and the blue light is emitted from a light-emitting diode (LED) formed by a nitride semiconductor. A nitride semiconductor including nitrogen (N) is a prime candidate to make a short-wave light-emitting device because its band-gap is sufficiently wide. Among other things, gallium nitride-based compound semiconductors have been researched and developed particularly extensively. As a result, blue LEDs, green LEDs, and semiconductor laser diodes made of GaN-based semiconductors have already been used in actual products.

FIG. 1A shows the structure of the conventional nitride semiconductor LED 1. The conventional nitride semiconductor LED 1 comprises an n-type semiconductor 2, a multiple quantum well structure 4 and a p-type semiconductor layer 6. In order to raise the lighting efficiency of the nitride semiconductor LED 1, the multiple quantum well structure 4 of the nitride semiconductor LED comprises the barrier layers 41 and the well layers 42 to form the traps to capture the electrons and holes to increase the combination efficiency thereof. Generally, the multiple quantum well structure 4 of the nitride semiconductor LED 1 is formed by multiple GaN layers and multiple InGaN layers stacked alternately. Nevertheless, the lattice constant of the GaN layer does not match the lattice constant of the InGaN layer and the piezoelectric polarization in the multiple quantum well structure 4 is happened. FIG. 1B shows the energy band structure (E_{c} and Eᵥ) of the multiple quantum well structure 4 is distorted when an electrical current 3 is applied to the nitride semiconductor LED 1. E_{c} is conductive energy band, and Eᵥ is valence energy band. The distorted energy band structure (E_{c} and Eᵥ) causes the electron wave function 31 and the hole wave function 32 separated so that the peak 311 of the electron wave function 31 does not align with the peak 321 of the hole wave function 32, and the distorted energy band structure (E_{c} and Eᵥ) also causes the electron overflowing. When the electron wave function 31 and the hole wave function 32 are separated and the electron overflows, the recombination efficiency of the electrons and the holes decreases and the light emitting efficiency is reduced. The situation that a distorted energy band structure (E_{c} and Eᵥ) makes the wave functions of electron and hole separated is named as quantum confined Stack effect (QCSE).

### SUMMARY OF THE DISCLOSURE

A light-emitting device comprises a semiconductor stacked structure, the semiconductor stacked structure comprising a p-type semiconductor layer, a n-type semiconductor layer and an multiple quantum well structure between the p-type semiconductor layer and the n-type semiconductor layer, wherein the active layer comprises a first multiple quantum well structure near the n-type semiconductor layer and a second multiple quantum well structure near the p-type semiconductor layer, wherein the first multiple quantum well structure has positive interface bound charge and the second multiple quantum well structure has zero interface bound charge.

### BRIEF DESCRIPTION OF THE DRAWINGS

FIG. 1A shows the structure of the conventional nitride semiconductor LED;

FIG. 1B shows that the energy band structure (E_{c} and Eᵥ) of the multiple quantum well structure 4 is distorted;

FIG. 2 shows the band gap energy versus lattice constant of AlGaInN series material;

FIG. 3A shows AlₓInN bandgap energy versus Al content of AlₓInN;

FIG. 3B shows AlₓInN interface bound charge versus Al content of AlₓInN;

FIG. 4A shows the energy band structure (E_{c} and Eᵥ) of the multiple quantum well structure is distorted when the interface bound charge of AlₓInN is in a range of 0 c/cm²˜0.01 c/cm²;

FIG. 4B shows that the energy band structure (E_{c} and Eᵥ) of the multiple quantum well structure is not distorted when the interface bound charge of AlₓInN is equal to 0;

FIG. 5A shows the multiple quantum well structure comprises a QCSE-reversed and a QCSE-free multiple quantum well structure;

FIG. 5B shows the distorted energy band structure (E_{c} and Eᵥ) of the QCSE-reversed and QCSE-free multiple quantum well structure in accordance with the first embodiment of the present application.

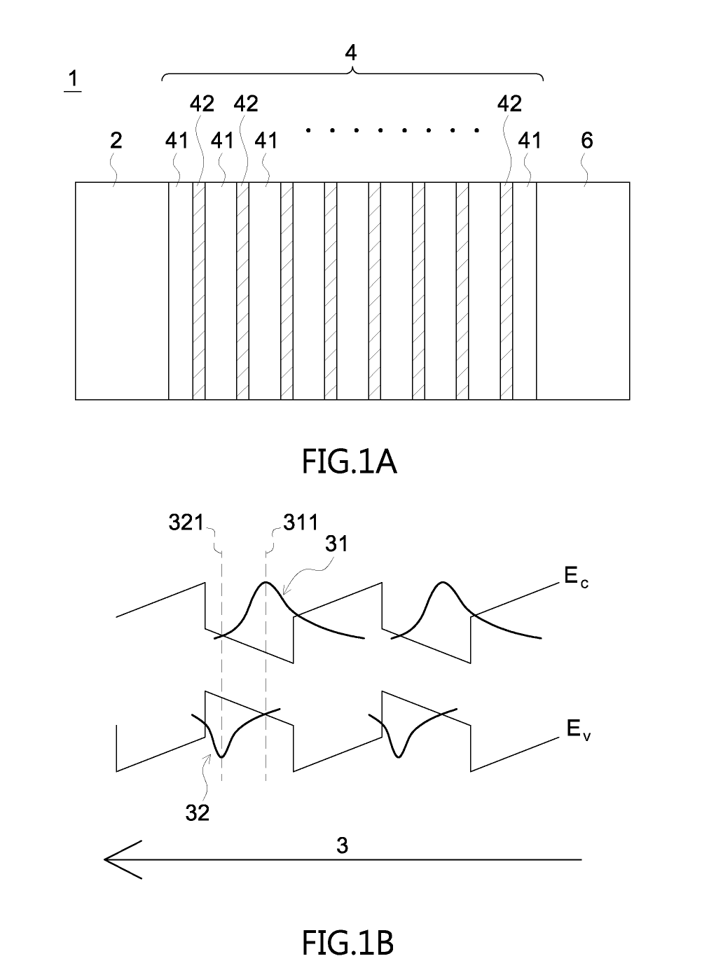

### DETAILED DESCRIPTION OF PREFERRED EMBODIMENTS

Exemplary embodiments of the present application will be described in detail with reference to the accompanying drawings hereafter. The following embodiments are given by way of illustration to help those skilled in the art fully understand the spirit of the present application. Hence, it should be noted that the present application is not limited to the embodiments herein and can be realized by various forms. Further, the drawings are not precise scale and components may be exaggerated in view of width, height, length, etc. Herein, the similar or identical reference numerals will denote the similar or identical components throughout the drawings.

### First Embodiment

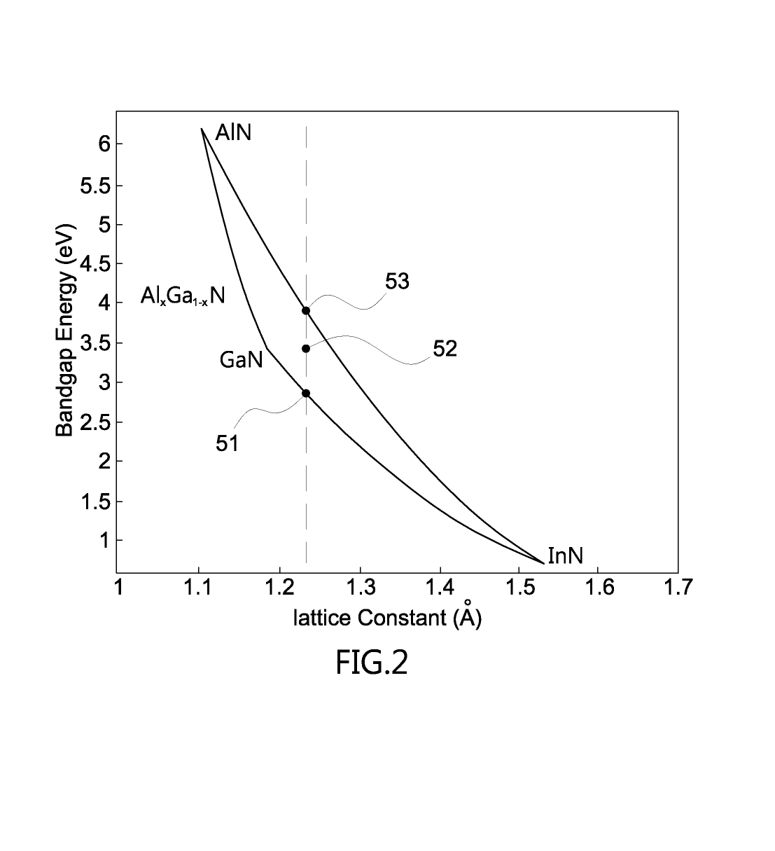

In order to avoid the wave functions of electron and hole being separated, the lattice constant of the barrier layers 41 has to match the lattice constant of the well layers 42. FIG. 2 shows the band gap energy versus lattice constant of AlGaInN material. In the first embodiment, the material of the well layers 42 is In_{b}Ga_{1-b}N 51. In FIG. 2, the material of which the lattice constant matches the lattice constant of the In_{b}Ga_{1-b}N 51 can be found in the vertical dotted line. To be more specific, AlₐIn₁₋ₐN 53 and Al_{c}In_{d}Ga_{1-c-d}N 52 on the dotted line can match the In_{b}Ga_{1-b}N 51.

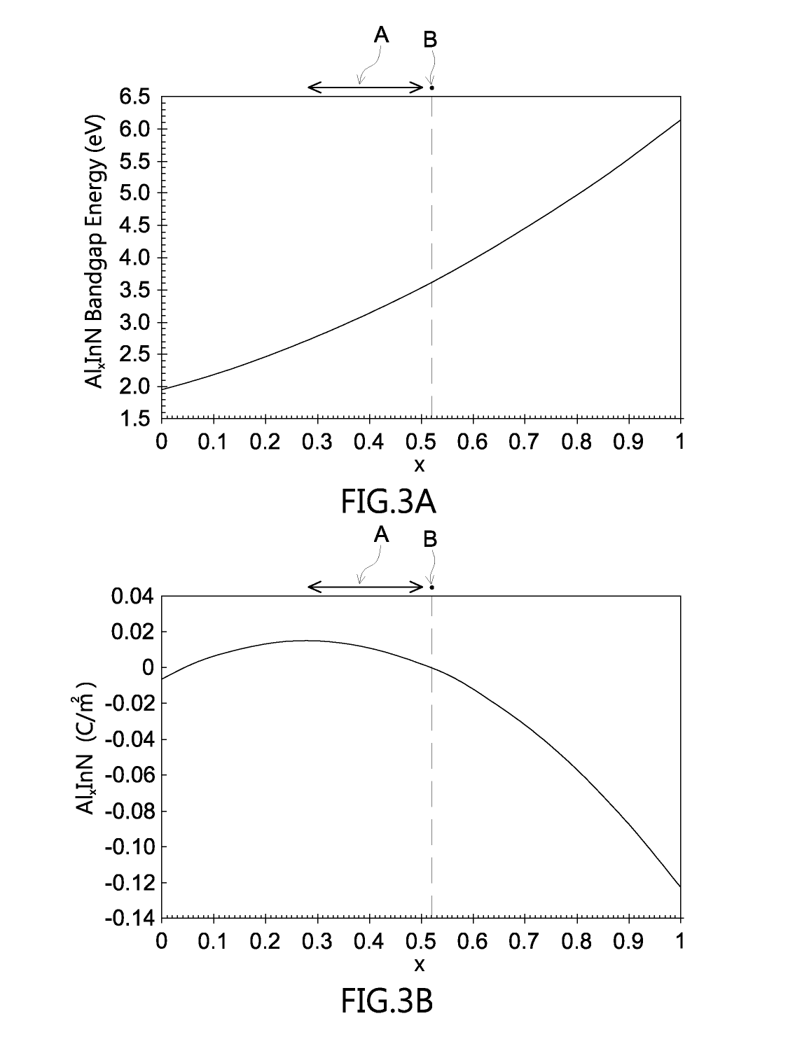

FIG. 3A shows AlₓInN band gap energy versus x, wherein x is Al content of AlₓInN. FIG. 3B shows AlₓInN interface bound charge versus x, wherein x is Al content of AlₓInN. In FIGS. 3A and 3B, region A represents 0.42≦x<0.54, region B represents x=0.54. In region A, the band gap energy of AlₓInN is between 3.2 eV˜3.62 eV and the interface bound charge of AlₓInN is in a range of 0 c/cm²˜0.01 c/cm². Region B represents x=0.54. In region B, the band gap energy of AlₓInN is 3.62 eV and the interface bound charge of AlₓInN is 0 c/cm².

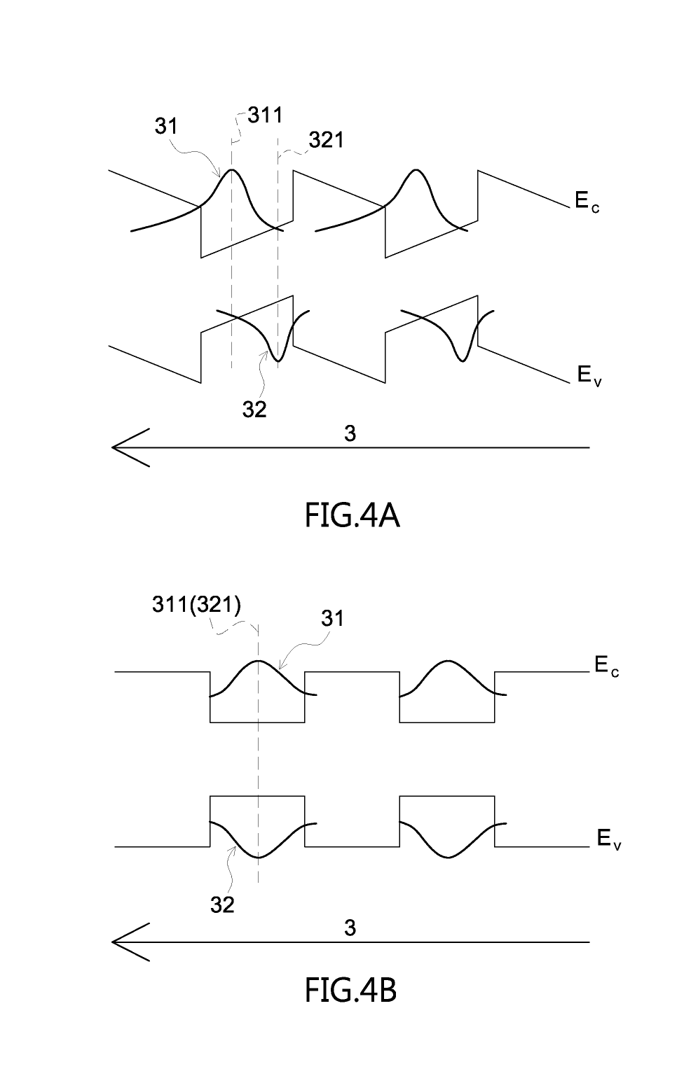

FIG. 4A indicates when an electrical current 3 flows through the multiple quantum well structure 4 which is formed by AlₓInN and InGaN, wherein the barrier layer is AlₓInN and the well layer is InGaN, and the interface bound charge and the band gap energy of AlₓInN are in the region A, the energy band structure of the multiple quantum well structure 4 is distorted and the reversed quantum confined Stack effect (QCSE-reversed) is occurred. Because the band gap energy of AlₓInN in the region A is between 3.2 eV˜3.62 eV and the band gap energy of InGaN is about 3 eV, the difference of the band gap energy between AlₓInN and InGaN can make the multiple quantum well structure 4 have better confining effect for the electron and hole. The distortion direction of the energy band structure which has reversed quantum confined Stack effect (QCSE-reversed) is opposite to the distortion direction of the energy band structure which has quantum confined Stack effect (QCSE). The distorted energy band structure which has reversed quantum confined Stack effect (QCSE-reversed) can reduce the electron overflowing.

FIG. 4B indicates that when an electrical current 3 flows through the multiple quantum well structure 4 which is formed by AlₓInN and InGaN wherein the interface bound charge and the energy bands of AlₓInN is in the region B, the energy band structure of the multiple quantum well structure 4 is not distorted. When the energy band structure of the multiple quantum well structure 4 is not distorted, and the wave functions of electron and hole are not separated. The situation that the energy band structure is not distorted is free quantum confined Stack effect (QCSE-free), and the recombination rate of the electrons and the holes can be increased.

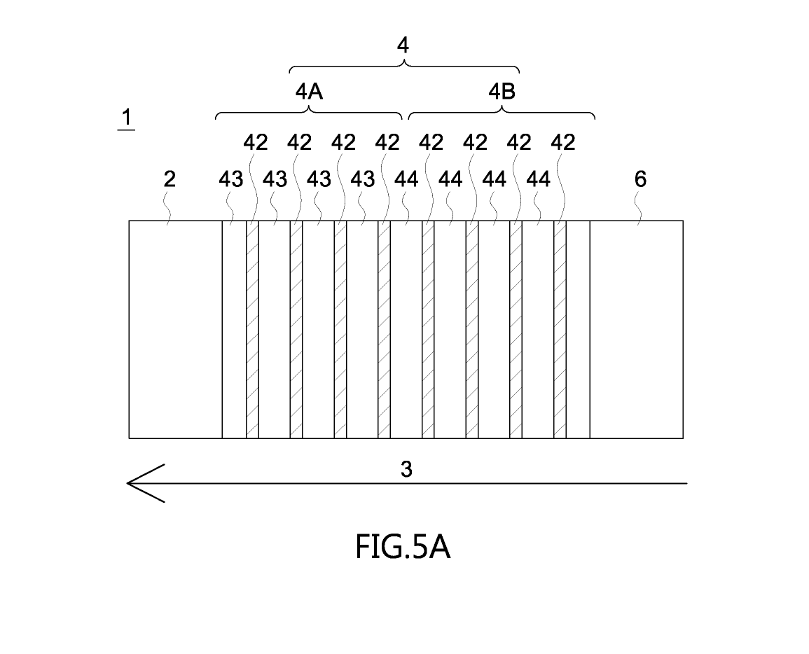

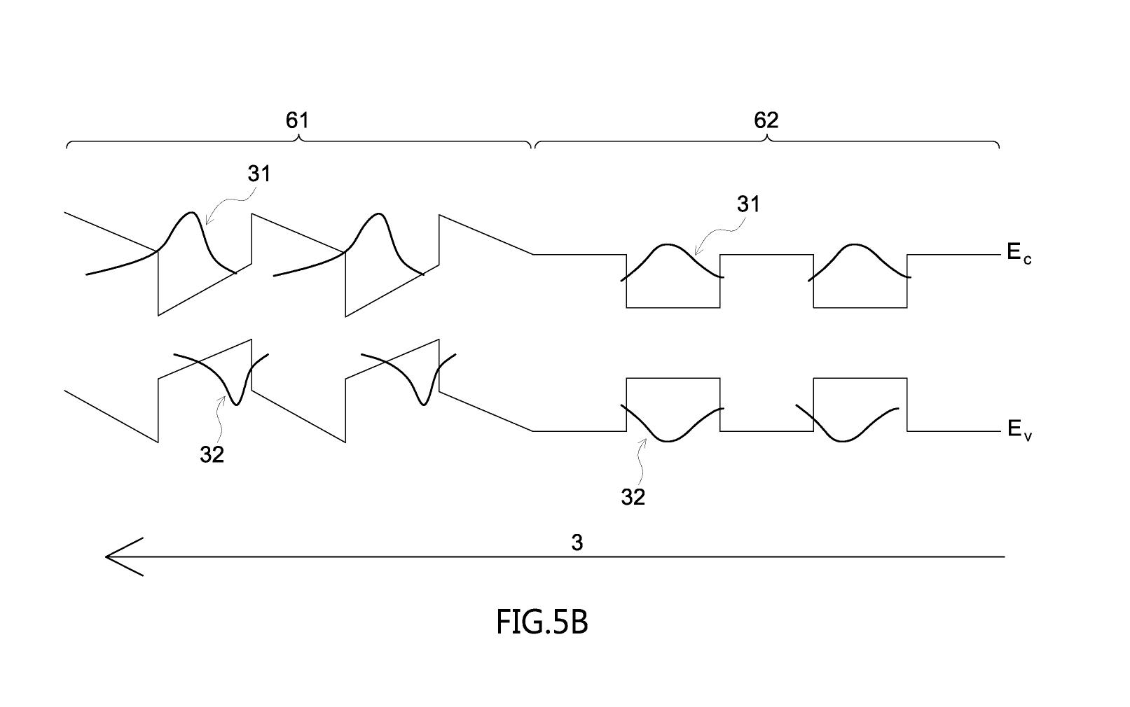

FIG. 5A shows the nitride semiconductor LED 1A comprises an n-type semiconductor layer 2, a multiple quantum well structure 4 and a p-type semiconductor layer 6. The material of the n-type semiconductor layer 2 and the p-type semiconductor layer 6 of the nitride semiconductor LED 1A is GaN series. The multiple quantum well structure 4 of the nitride semiconductor LED 1A comprises a QCSE-reversed multiple quantum well structure 4A and a QCSE-free multiple quantum well structure 4B. The QCSE-reversed multiple quantum well structure 4A is near the n-type semiconductor layer 2, and the QCSE-free multiple quantum well structure 4B is near the p-type semiconductor layer 6. The QCSE-reversed multiple quantum well structure 4A comprises the first barrier layers 43 and the well layers 42, wherein the first barrier layers 43 and the well layers 42 are stacked alternately. The material of the well layer 42 is InGaN, and the material of the first barrier layers 43 is AlₓInN, wherein 0.42≦x<0.54. The QCSE-free multiple quantum well structure 4B comprises the second barrier layers 44 and the well layers 42, wherein the second barrier layers 44 and the well layers 42 are stacked alternately. The material of the well layer 42 is InGaN, and the material of the second barrier layers 44 is AlₓInN, wherein x=0.54. The concentration of Al of the second barrier layers 44 is greater than the concentration of Al of the first barrier layers 43. FIG. 5B indicates that when an electric current is applied to the nitride semiconductor LED 1A, the energy band structure (E_{c} and Eᵥ) of the multiple quantum well structure 4 has the distorted region 61 and the non-distorted region 62. The distorted region 61 represents the energy band structure of the QCSE-reversed multiple quantum well structure 4A, and the non-distorted region 62 represents the energy band structure of the QCSE-free multiple quantum well structure 4B. Because the QCSE-reversed multiple quantum well structure 4A can reduce the electron overflowing and the QCSE-free multiple quantum well structure 4B can raise the recombination rate of the electrons and the holes, the multiple quantum well structure 4 has a better light emitting efficiency.

The foregoing description of preferred and other embodiments in the present disclosure is not intended to limit or restrict the scope or applicability of the inventive concepts conceived by the Applicant. In exchange for disclosing the inventive concepts contained herein, the Applicant desires all patent rights afforded by the appended claims. Therefore, it is intended that the appended claims include all modifications and alterations to the full extent that they come within the scope of the following claims or the equivalents thereof.

What is claimed is:

1. A light-emitting device, comprising:
a semiconductor stacked structure, the semiconductor stacked structure comprising a p-type semiconductor layer; a n-type semiconductor layer; and
an multiple quantum well structure between the p-type semiconductor layer and the n-type semiconductor layer,
wherein the multiple quantum well structure comprises a first multiple quantum well structure near the n-type semiconductor layer and a second multiple quantum well structure near the p-type semiconductor layer,
wherein the first multiple quantum well structure has positive interface bound charge and the second multiple quantum well structure has a smaller interface bound charge.

2. A light-emitting device according to claim 1, wherein the interface bound charge of the second multiple quantum well structure is substantially zero.

3. A light-emitting device according to claim 1, wherein the multiple quantum well structure comprises a plurality of well layers, and the first multiple quantum well structure comprises a plurality of first barrier layers and the second multiple quantum well structure comprises a plurality of second barrier layers.

4. A light-emitting device according to claim 1, wherein the first multiple quantum well structure having positive interface bound charge reduces the electron overflowing.

5. A light-emitting device according to claim 1, wherein the second multiple quantum well structure having smaller interface bound charge raises the recombination rate of electrons and holes.

6. A light-emitting device according to claim 3, wherein the plurality of the first barrier layers and the plurality of the second barrier layers contain Al, and the concentration of Al of the plurality of second barrier layers is greater than the concentration of Al of the plurality of first barrier layers.

7. A light-emitting device according to claim 3, wherein the plurality of first barrier layers and the plurality of well layers are alternately stacked, and the plurality of second barrier layers and the plurality of well layers are alternately stacked.

8. A light-emitting device according to claim 3, wherein the plurality of well layers comprises InGaN.

9. A light-emitting device according to claim 3, wherein the plurality of first barrier layers comprises AlₓInN, wherein 0.42≦x<0.54.

10. A light-emitting device according to claim 3, wherein the plurality of second barrier layers comprises Al_{y}InN, wherein y=0.54.

11. A light-emitting device according to claim 3, wherein the band gap energy of the plurality of first barrier layers is greater than 3.2 eV.

12. A light-emitting device according to claim 3, wherein the band gap energy of the plurality of second barrier layers is equal to 3.62 eV.
